(19) United States
(12) Patent Application Publication
(10) Pub. No.: US 2011/0005458 A1
(43) Pub. Date: Jan. 13, 2011

(54) METHOD AND APPARATUS FOR IMPROVING SCRIBE ACCURACY IN SOLAR CELL MODULES

(75) Inventor: KEVIN LAUGHTON CUNNINGHAM, Mountain View, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/817,485

(22) Filed: Jun. 17, 2010

Related U.S. Application Data
(60) Provisional application No. 61/225,096, filed on Jul. 13, 2009.

(51) Int. Cl. B05C 11/00; B05C 21/00; B23K 26/00

(52) U.S. Cl. 118/663; 219/121.68; 219/121.69

(57) ABSTRACT

Embodiments of the present invention generally relate to a process and apparatus for monitoring and controlling the accuracy and spacing of isolation trenches scribed in a solar module during the fabrication process. In one embodiment, encoder marks, and optionally, encoder lines are scribed into a front contact layer of a solar cell device substrate. The encoder marks and lines may then be used via one or more subsequent scribe modules to control the pulsing and positioning of a laser device to provide accurate and consistent trench lines in various layers of the completed solar module.

### CROSS-REFERENCE TO RELATED APPLICATIONS

This application claims benefit of U.S. provisional patent application Ser. No. 61/225,096, filed Jul. 13, 2009, which is herein incorporated by reference.

### BACKGROUND OF THE INVENTION

1. Field of the Invention

Embodiments of the present invention generally relate to the fabrication of photovoltaic modules. In particular, embodiments of the present invention relate to apparatus and methods for providing accurate and consistent scribes in solar modules during the fabrication process.

2. Description of the Related Art

Photovoltaic (PV) cells or solar cells are devices that convert sunlight into direct current (DC) electrical power. Typical thin film solar cells have a PV layer comprising one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect.

Thin film solar cells are typically formed in series on a large area substrate to form a solar module. The solar modules are formed by scribing trenches in the various thin film layers deposited on the large area substrate during the fabrication process to both isolate and electrically connect the solar cells in series. In order to maximize the efficiency of the solar module, the spacing of the various scribed trenches should be minimized. However, certain scribing issues, such as gaps in the scribed trenches or non-parallelism of the scribed trenches, are experienced during the solar module fabrication process. Such issues lead to non-functioning or “dead” cells resulting in significant losses in the efficiency of the solar module. Moreover, these “dead” cells are typically not discovered until final testing of the completed solar module using prior are process sequences and fabrication techniques.

Therefore, there is a need for a method and apparatus for providing accurate and consistent scribes during the fabrication of a solar module. Additionally, there is a need for a process and system for fabricating solar modules incorporating scribe modules and methods to improve the various scribing processes and reduce or prevent the occurrence of “dead” solar cells in solar modules.

### SUMMARY OF THE INVENTION

In one embodiment of the present invention, an apparatus for scribing lines in one or more layers disposed on a first surface of a solar cell device substrate comprises a substrate handling device configured to support and move the device substrate, wherein the substrate handling device supports the device substrate in a position with the first surface facing upwardly. The apparatus further comprises a laser device positioned below a second surface of the device substrate that is opposite the first surface and configured to remove a portion of at least one of the one or more layers from the device substrate, a vision system positioned below the second surface of the device substrate and configured to monitor one or more edge regions of the device substrate while the portion of at least one of the one or more layers is removed from the device substrate, and a system controller in communication with the substrate handling device, the laser device, and the vision system, wherein the system controller is configured to control removal of the portion of at least one of the one or more layers from the device substrate based on information received from the vision system regarding the one or more monitored edge regions.

In another embodiment, a method for scribing lines in one or more layers of a solar cell device substrate comprises causing relative motion between the device substrate and a laser device in a first direction, illuminating an edge region of the device substrate having a plurality of encoder marks scribed therein during the relative motion, capturing images of the plurality of encoder marks within the edge region during the illuminating the edge region, and pulsing the laser device based on the captured images of the plurality of encoder marks within the edge region of the device substrate.

In another embodiment, a system for fabricating solar cell modules comprises a first scribing module having a first laser device and a first vision system, wherein the first laser device is configured to scribe a plurality of encoder marks on a substrate, wherein the first laser device is further configured to scribe one or more first trenches in a front contact layer disposed on the substrate, and wherein the first vision system is configured to monitor the plurality of encoder marks while the first laser device scribes the one or more first trenches. The system further comprises one or more cluster tools having at least one chamber configured to deposit at least one photovoltaic layer over the front contact layer and a second scribing module having a second laser device and a second vision system, wherein the second laser device is configured to scribe one or more second trenches in the at least one photovoltaic layer of the substrate, and wherein the second vision system is configured to monitor the plurality of encoder marks while the second laser device scribes the one or more second trenches. The system also comprises a system controller configured to control the first laser device based on information received from the first vision system and configured to control the second laser device based on information received from the second vision system.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a simplified, schematic flow chart illustrating one embodiment of a process sequence including a plurality of processes used to form a solar module using a solar module production line.

FIG. 2 is a simplified, schematic plan view of one embodiment of the solar cell module production line illustrating process modules for use with the process sequence of FIG. 1.

FIG. 3 is a schematic plan view of a solar module having a plurality of solar cells formed on a substrate.

FIG. 4 is a schematic, cross-sectional view of a portion of the solar module along section line 4-4 shown in FIG. 3.

FIG. 5A is a schematic, plan view of a scribe module that may be used for laser scribing a series of trenches in one or more material layers deposited on a solar cell substrate.

FIG. 5B is a schematic, cross-sectional view of the scribe module depicted in FIG. 5A.

FIGS. 6A and 6B are enlarged views of a region of the solar module depicted in FIG. 3 illustrating possible orientation of scribed trenches that result in nonfunctioning solar cells.

FIG. 7 is schematic, plan view of a device substrate having encoder marks and lines according to one embodiment of the present invention.

FIG. 8 is a schematic, cross-sectional view of the scribe module in FIG. 5 incorporating a vision system according to one embodiment of the present invention.

For clarity, identical reference numerals have been used, where applicable, to designate identical elements that are common between figures. It is contemplated that features of one embodiment may be incorporated in other embodiments without further clarification.

### DETAILED DESCRIPTION

Embodiments of the present invention generally relate to a process and apparatus for monitoring and controlling the accuracy and spacing of isolation trenches scribed in a solar module during the fabrication process. In one embodiment, encoder marks, and optionally, encoder lines are scribed into a front contact layer of a solar cell device substrate. The encoder marks and lines may then be used via one or more subsequent scribe modules to control the pulsing and positioning of a laser device to provide accurate and consistent trench lines in various layers of the completed solar module.

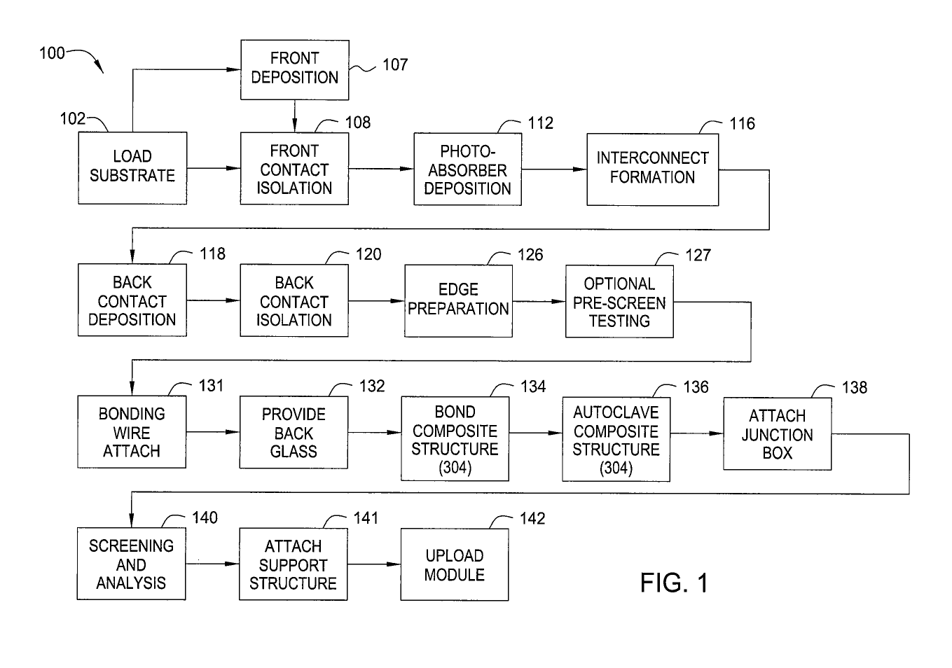

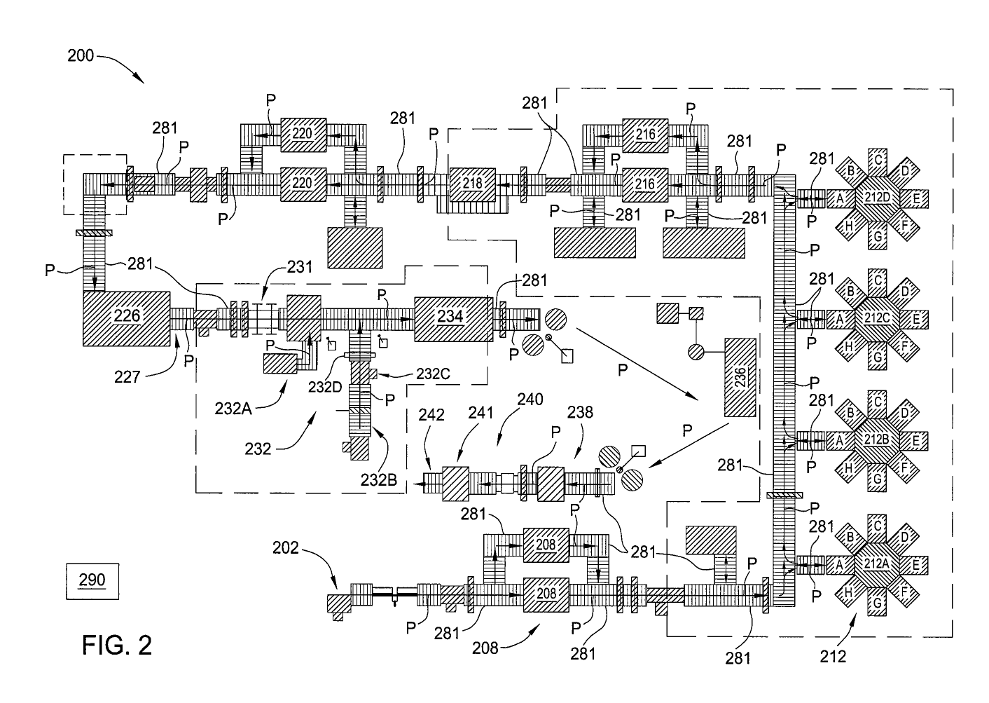

FIG. 1 is a simplified, schematic flow chart illustrating one embodiment of a process sequence 100 including a plurality of processes used to form a solar module 300 using a solar module production line 200. FIG. 2 is a simplified, schematic plan view of one embodiment of the production line 200 illustrating process modules and other aspects of the system design.

In general, a system controller 290 may be used to control one or more components found in the production line 200. The system controller 290 generally facilitates the control and automation of the overall production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 290 determines which tasks are performable on a substrate. Preferably, the program is software readable by the system controller 290 that includes code to perform tasks relating to monitoring, execution and control of the movement, support, and/or positioning of a substrate along with the various process recipe tasks and various chamber process recipe steps being performed in the production line 200. In one embodiment, the system controller 290 also contains a plurality of programmable logic controllers (PLC's) that are used to locally control one or more modules in the solar cell production, and a material handling system controller (e.g., PLC or standard computer) that deals with the higher level strategic movement, scheduling and running of the complete production line 200.

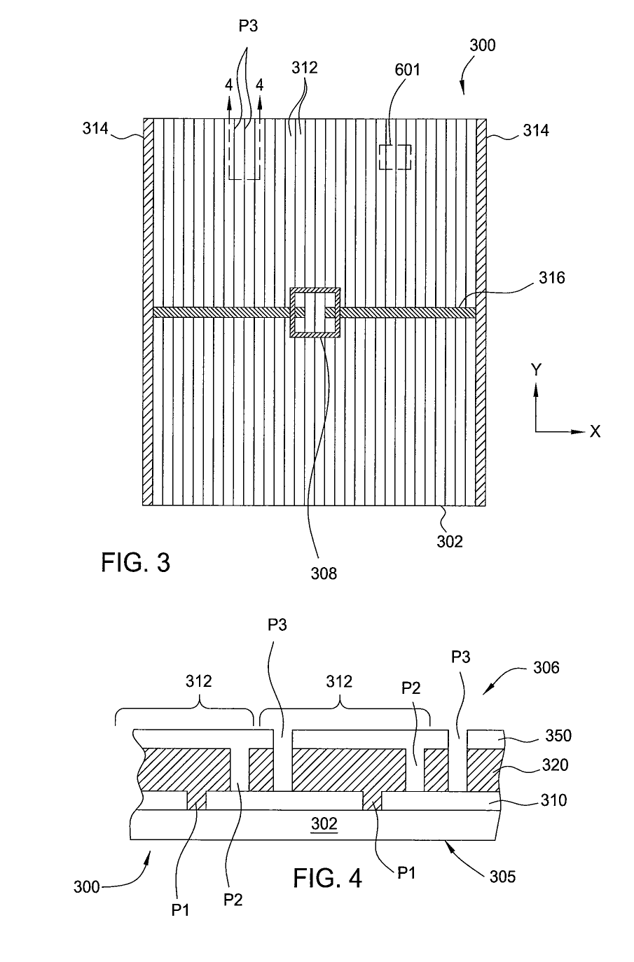

FIG. 3 is a schematic plan view of a solar module 300 having a plurality of solar cells 312 formed on a substrate 302. The plurality of solar cells 312 are electrically connected in series and are electrically connected to side busses 314 located at opposing ends of the solar module 300. A cross-buss 316 is electrically connected to each of the side busses 314 to collect the current and voltage generated by the solar cells 312. A junction box 308 acts as an interface between leads (not shown) from the cross-busses 316 and external electrical components that will connect to the solar module 300, such as other solar modules or a power grid.

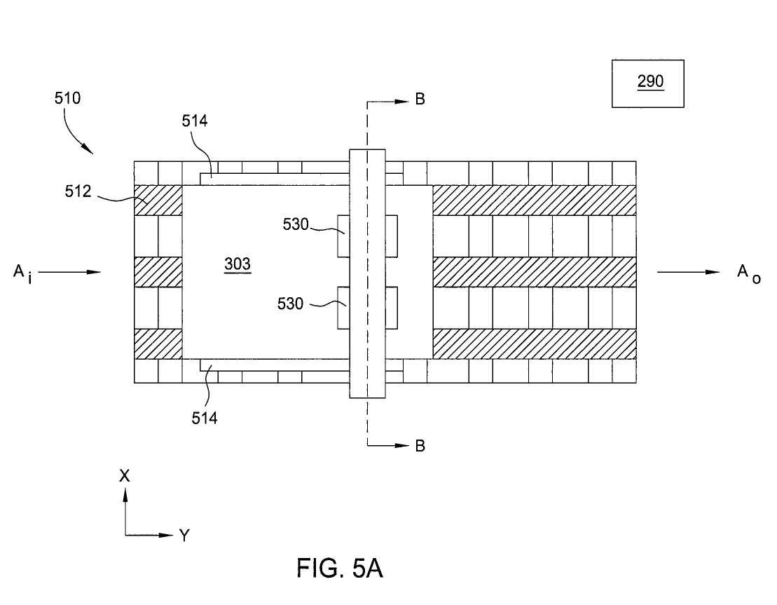

In order to form a desired number and pattern of solar cells 312 on the substrate 302, a plurality of scribing processes may be performed on material layers formed on the substrate 302 to achieve cell-to-cell and cell-to edge isolation. FIG. 4 is a schematic cross-sectional view of a portion of the solar module 300 along section line 4-4 shown in FIG. 3. As shown, the solar module 300 includes the substrate 302, such as a glass substrate, polymer substrate, metal substrate, or other suitable substrate, having a front surface 305 with thin films formed over the substrate 302 on a back surface 306 opposite the front surface 305 of the substrate 302. In one embodiment, the substrate 302 is a glass substrate that is about 2200 mm×2600 mm×3 mm in size. The solar module 300 further includes a front contact layer 310 formed over back surface 306 of the substrate 302. The front contact layer 310 may be any optically transparent and electrically conductive film, such as a transparent conducting oxide (TCO), formed to serve as a front contact electrode for the solar cells 312. Examples of TCO include zinc oxide (ZnO) and tin oxide (SnO). The solar module 300 further includes a photovoltaic (PV) layer 320 formed over the front contact layer 310 and a back contact layer 350 formed over the PV layer 320.

The PV layer 320 may include a plurality of silicon film layers that includes one or more p-i-n junctions for converting energy from incident photons into electricity through the PV effect. In one configuration, the PV layer 320 comprises a first p-i-n junction having a p-type amorphous silicon layer, an intrinsic type amorphous silicon layer formed over the p-type amorphous silicon layer, and an n-type amorphous silicon layer formed over the intrinsic type amorphous silicon layer. In one example, the p-type amorphous silicon layer is formed to a thickness between about 60 Å and about 300 Å; the intrinsic type amorphous silicon layer is formed to a thickness between about 1500 Å and about 3500 Å; and the n-type amorphous semiconductor layer is formed to a thickness between about 100 Å and about 500 Å. In one embodiment, instead of the n-type amorphous silicon layer, an n-type microcrystalline semiconductor layer is formed to a thickness between about 100 Å and about 400 Å.

In another configuration, the PV layer 320 further comprises a second p-i-n junction over the first p-i-n junction. In one example, the second p-i-n junction comprises a p-type microcrystalline silicon layer formed to a thickness from about 100 Å and about 400 Å, an intrinsic type microcrystalline silicon layer formed to a thickness between about 10,000 Å and about 30,000 Å over the p-type microcrystalline silicon layer, and an n-type amorphous silicon layer formed over the intrinsic type microcrystalline silicon layer at a thickness between about 100 Å and about 500 Å.

The back contact layer 350, which is formed over the PV layer 320, may include one or more conductive layers adapted to serve as a back electrode for the solar cells 312. Examples of materials that may comprise the back contact layer 350 include, but are not limited to aluminum (Al), Silver (Ag), titanium (Ti), chromium (Cr), gold (Au), copper (Cu), platinum (Pt), alloys thereof, or combinations thereof.

Three scribing steps may be performed to produce trenches P1, P2, and P3, which are required to form a high efficiency solar cell device, such as the solar module 300. Although formed together on the substrate 302, the individual cells 312 are isolated from each other by the insulating trench P3 formed in the back contact layer 350 and the PV layer 320. In addition, the trench P2 is formed in the PV layer 320 so that the back contact layer 350 is in electrical contact with the front contact layer 310. In one embodiment, the insulating trench P1 is formed by laser removal of a portion of the front contact layer 310 prior to the deposition of the PV layer 320 and the back contact layer 350. Similarly, in one embodiment, the trench P2 is formed in the PV layer 320 by the laser scribe removal of a portion of the PV layer 320 prior to the deposition of the back contact layer 350. Finally, in one embodiment, the trench P3 is formed by the laser removal of portions of the back contact layer 350 and the PV layer 320.

To avoid confusion relating to the actions specifically performed on the substrates 302 in the following description, a substrate 302 having one or more of the deposited layers (e.g., the front contact layer 310, the PV layer 320, or the back contact layer 350) and/or one or more internal electrical connections (e.g., side buss 314, cross-buss 316) disposed thereon is referred to as a device substrate 303. Similarly, a device substrate 303 that has been bonded to a back glass substrate using a bonding material is referred to as a composite solar cell structure 304.

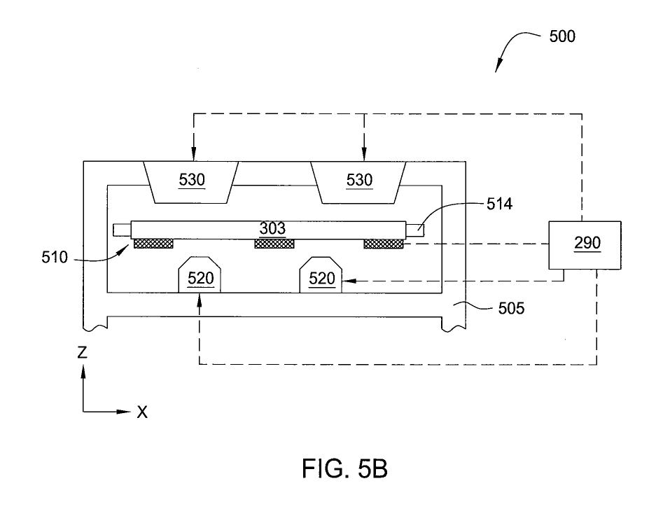

Typically laser scribing of the trenches P1, P2, and P3 are respectively performed in laser scribe modules. FIG. 5A is a schematic plan view and FIG. 5B is a schematic, cross-sectional view of a scribe module 500 that may be used for laser scribing a series of trenches (i.e., P1, P2, or P3) in one or more material layers (i.e., front contact layer 310, PV layer 320, or back contact layer 350) deposited on the solar cell substrate 302. In one embodiment, the scribe module 500 generally includes a substrate handling system 510, one or more laser devices 520, and an exhaust assembly 530, all coordinated and controlled by the system controller 290.

In general operation, a device substrate 303 is transferred into the scribing module 500 following the path Aᵢ. The device substrate 303 is oriented with the surface having one or more layers (e.g., front contact layer 310, PV layer 320, back contact layer 350) facing upwardly. The device substrate 303 is then passed over the laser devices 520 one or more times while a series of trenches (i.e., P1, P2, or P3) are scribed into the device substrate 303. The device substrate 303 then exits the scribe module 500 following path Aₒ.

In one embodiment, each laser device 520 comprises a laser source (e.g., Nd:YV0₄ laser), various optics, and other support components that are used to control the power, energy, and timing of the delivery of energy used to scribe the desired trenches (e.g., P1, P2, or P3) into the respective layer (e.g., front contact layer 310, PV layer 320, or back contact layer 350) in the device substrate 303. In one embodiment, the one or more laser devices 520 are located below the device substrate 303. In one embodiment, a portion of the exhaust assembly 530 is located above the device substrate 303, in order to effectively exhaust material that is ablated or otherwise removed from the device substrate 303 via the respective laser device 520.

In one embodiment, the substrate handling system 510 includes a support structure 505 that is positioned beneath the device substrate 303 and is adapted to support and retain the various components used to perform laser scribing processes on the device substrate 303. In one embodiment, the substrate handling system 510 includes a conveyor system 512 that has a plurality of conventional, automated conveyor belts for positioning and transferring the device substrate 303 within the scribe module 500 in a controlled and automated fashion.

In one embodiment, the substrate handling system 510 further includes one or more substrate grippers 514 for retaining and moving the device substrate 303 during laser scribing processes. The substrate grippers 514 are used to grip the edges of the device substrate 303 and include an actuator, such as a linear motor, to translate the device substrate 303 in the Y and −Y directions while the laser devices 520 form the trenches (e.g., P1, P2, or P3) into the desired layers of the device substrate 303.

Typically laser scribing of the trenches (P1, P2, or P3) in the device substrate 303 is performed by a laser device 520 that is pulsed to ablate material from the desired layer of the device substrate 303 in the form of a “spot.” Either the device substrate 303 or the laser device 520 is linearly moved in order to create a “line” of overlapping spots resulting in the lines of trenches (P1, P2, or P3). However, certain movements of the device substrate 303 with respect to the laser device 520 may result in nonfunctioning or “dead” regions or cells 312 within the completed solar module 300.

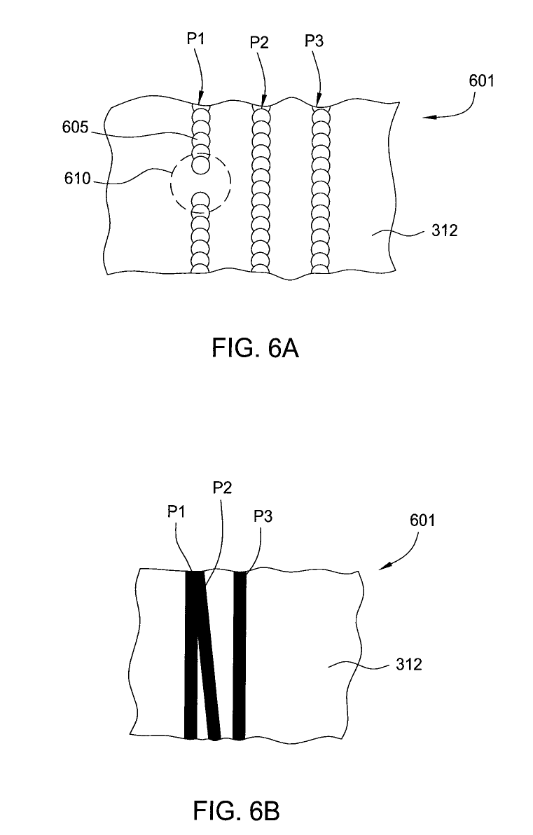

FIGS. 6A and 6B represent enlarged views of a region 601 of the solar module 300 depicted in FIG. 3 illustrating possible orientations of the trenches P1, P2, and P3 that result in nonfunctioning cells 312. FIG. 6A depicts an enlarged view of the region 601 of the solar module 300 showing one example of an orientation of trenches P1, P2, and P3 resulting in a nonfunctioning cell 312. As shown, the lines of trenches P1, P2, and P3 comprise a series of overlapping laser spots 605. As seen in FIG. 6A, the trench P1 has a missing or mis-spaced laser spot 605 at a location 610. Such a situation may occur due to variations in acceleration or deceleration of the device substrate 303 by the grippers 514 as the device substrate 303 is moved relative to the laser device 520 during the scribing process. Additionally, vibrations induced from an outside source may cause a missing or mis-spaced laser spot 605 during laser pulsing. The result of this condition is a short in the cell 312 resulting in at least one nonfunctioning cell 312, which reduces the overall efficiency of the solar module 300.

FIG. 6B depicts an enlarged view of the region 601 of the solar module 300 showing another example of an orientation of trenches P1, P2, and P3 resulting in a nonfunctioning cell 312. As seen in FIG. 6B, the trenches P1, P2, and P3 are nonparallel, resulting in overlapping scribed regions in the respective layers (front contact layer 310, PV layer 320, and back contact layer 350). This situation may occur due to the orientation of the device substrate 303 becoming skewed relative to the axis of movement (e.g., Y and −Y directions) as it is processed in one of the scribe modules 500. The result of this condition is also a short in the cell 312, resulting in at least one nonfunctioning cell 312, which reduces the overall efficiency of the solar module 300. Additionally, because the spacing of the scribed trenches P1, P2, and P3 are typically from about 100 μm to about 240 μm, small variations in the trench placement can lead to nonfunctioning cells 312 as well.

In an attempt to address laser pulsing issues and scribe alignment issues, prior art laser scribe modules have incorporated visual encoders on the substrate grippers 514. In this configuration, the position of the substrate grippers 514 can be tracked and controlled during the laser scribing process. However, device substrate 303 movement with respect to the grippers 514 may occur in the module 500 for a number of reasons, such as vibrations introduced into the module 500 from outside sources. Thus, relying on the position of the substrate grippers 514 does not consistently provide enough information to the system controller 290 to ensure that the pulsing of the laser device 520 provides consistent laser spots 605 and forms substantially parallel lines of trenches (e.g., P1, P2, P3) in the device substrate 303.

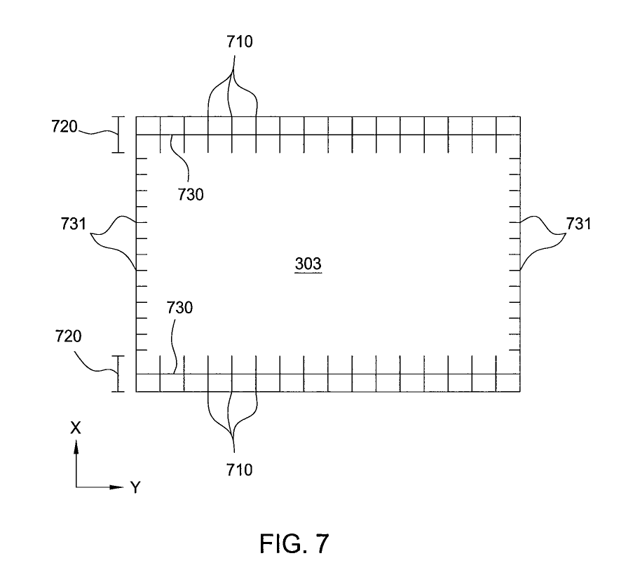

FIG. 7 is a schematic, plan view of a device substrate 303 having encoder marks and lines scribed therein according to one embodiment of the present invention. In one embodiment, encoder marks 710 are scribed in the front contact layer 310 in one or more edge regions 720 of the device substrate 303 via the scribe module 500. In one embodiment, the encoder marks 710 are scribed into the front contact layer 310 of each device substrate 303 in a direction substantially perpendicular to the direction of movement of the device substrate 303 through the scribe module 500, and therefore, substantially perpendicular to the subsequently scribed trenches P1, P2, and P3. In another embodiment, an additional encoder line 730 is scribed into the front contact layer 310 of each device substrate 303 in a direction substantially parallel to the direction of movement of the device substrate 303 through the scribe module 500, and therefore, substantially parallel to the subsequently scribed trenches P1, P2, and P3. In yet another embodiment, an additional group of encoder lines 731 are scribed into the front contact layer 310 of each device substrate 303 in a direction substantially parallel to the direction of movement of the device substrate 303, and therefore, substantially parallel to the subsequently scribed trenches P1, P2, and P3. The additional encoder lines 730 and/or 731 may be used to monitor movement of the device substrate 303 in the X-direction and/or alignment of the device substrate 303 in the X and Y-directions.

In one embodiment, the encoder marks 710 are scribed in one edge region 720 of the device substrate 303. In another embodiment, the encoder marks 710 are scribed in two opposing edge regions 720 of the device substrate 303. In one embodiment, each edge region 720 is from between about 10 mm to about 20 mm in width and runs substantially along the entire length of the device substrate 303. In one embodiment, the encoder marks 710 are from between about 3 mm and about 18 mm in length and are spaced from between about 150 μm and about 300 μm apart. In one embodiment, the edge region 720 corresponds to the region of the device substrate 303 that has the front contact layer 310, the PV layer 320, and the back contact layer 350 removed during an edge deletion step of the process sequence 100, as subsequently discussed. In one embodiment, the edge region 720 also includes the region of the device substrate 303 that is subsequently covered by the side buss 314.

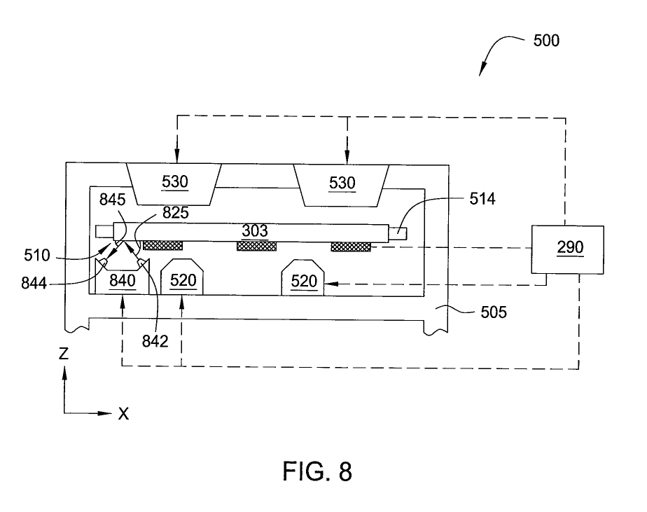

FIG. 8 is a schematic, cross-sectional view of the scribe module 500 incorporating a vision system 840 according to one embodiment of the present invention. In one embodiment, the vision system 840, in conjunction with the system controller 290, is used to monitor the positioning and advancement of the device substrate 303 on the substrate handling system 510 during the scribing process performed by the laser device 520 during forming one or more lines of the trenches (P1, P2, or P3). In one embodiment, the vision system 840 is positioned beneath the device substrate 303 and generally includes an illumination source 842 and an inspection device 844. In one embodiment, the illumination source 842 is positioned below the device substrate 303 and is configured to emit light toward the front surface 305 of the device substrate 303 at an angle 825 with respect to the surface of the device substrate 303. In one embodiment, the illumination source 842 is a broad band light source. In one embodiment, the illumination source 842 is a broad band illumination source. In one embodiment, the illumination source 842 includes one or more filters to control the wavelength of light emitted therefrom. In one embodiment, the illumination source 842 is configured to emit wavelengths of light only in a particular spectrum, such as the red spectrum or the blue spectrum. Emitting light in a particular spectrum provides greater optical contrast because different wavelengths of light are absorbed by different layers of the device substrate 303. In one embodiment, light is emitted in at a wavelength between about 400 nm and about 900 nm.

In one embodiment, the inspection device 844 comprises an imaging device (e.g., charge coupled device (CCD) camera, CMOS device) and other supporting components that are used to conduct optical inspection of the encoder marks 710 and encoder lines 730. In one embodiment, the inspection device 844 comprises one or more CCD cameras positioned below the device substrate 303 and configured to capture images at an angle 845 with respect to the surface of the device substrate. In one embodiment, the angle 845 is substantially complementary to the angle 825.

In operation, a scribe module 500 is positioned to receive a device substrate 303. The device substrate 303 may be received onto the substrate handling system 510 of the scribe module 500 with the front contact layer 310 facing upwardly, opposite the laser devices 520. In one embodiment, the substrate grippers 514 grasp opposite edges of the device substrate 303. Next, a series of encoder marks 710 are scribed in the front contact layer 310 in one or more edge regions 720 of the device substrate 303. In one embodiment, an encoder line 730 is also scribed in the one or more edge regions 720 of the device substrate 303 substantially perpendicular to the encoder marks 710.

Next, a series of lines of trenches P1 are scribed into the front contact layer 310 of the device substrate 303 by the laser devices 520 substantially perpendicular to the encoder marks 710 as the device substrate 303 is moved in the Y and then −Y directions. As the trenches P1 are being scribed by the laser devices 520, the vision system 840 is monitoring the encoder marks 710 and, optionally, the encoder lines 730 and/or 731. In one embodiment, as the device substrate 303 is advanced, the illumination source 842 emits light toward the encoder marks 710 and the encoder lines 730 (if present) while the inspection device 844 captures images of the reflected light and communicates the image in real time to the system controller 290. In response to the received images, the system controller 290 may control the energy delivered from each laser device 520 and the positioning of each laser device 520 in the X direction as the device substrate 303 is moved in the Y and/or −Y directions. In one embodiment, the system controller 290 adjusts the frequency and/or positioning of pulses delivered by each laser device 520 based on the received images. In one embodiment, the laser devices 520 and the vision system 840 are attached to one or more actuators (not shown), such as linear motors, and moved in the Y and/or −Y directions during laser scribing while the device substrate 303 is held in place.

In one embodiment, the encoder marks 710 and, optionally, the encoder lines 730 and/or 731 are used in subsequent scribe modules 500 for producing trenches P2 and P3 in the device substrate 303. A description of scribe modules 500 and corresponding processes for accurately and consistently producing trenches P1, P2, and P3 in a device substrate 303 within a solar module production line, such as the production line 200, according to one embodiment of the present invention follows.

### General Solar Module Formation

Referring to FIGS. 1 and 2, the process sequence 100 generally starts at step 102 in which a substrate 302 is loaded into a loading module 202 found in the solar module production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar device and thus reduces the solar cell device cost, facilities costs, and production costs of the finally formed solar cell device. However, typically, it is advantageous to receive “raw” substrates 302 that have a transparent conducting oxide (TCO) layer (e.g., front contact layer 310) already deposited on a surface of the substrate 302 before it is received into the system in step 102. If a conductive layer is not deposited on the surface of the “raw” substrates then a front contact deposition step (step 107), which is discussed below, needs to be performed on a surface of the substrate 302.

Referring to FIGS. 1 and 2, in one embodiment, prior to performing step 108 the substrate 302 is transported to a front end processing module (not illustrated in FIG. 2) in which a front contact formation step 107 is performed on the substrate 302. In one embodiment, the front end processing module is similar to the processing module 218 discussed below. In step 107, one or more substrate front contact formation steps may include one or more preparation, etching and/or material deposition steps that are used to form the front contact regions on a bare solar cell substrate 302. In one embodiment, step 107 generally comprises one or more physical vapor deposition (PVD) steps that are used to form the front contact region on a surface of the substrate 302. In one embodiment, the front contact region contains a transparent conducting oxide (TCO) layer that may contain metal element selected from a group consisting of zinc (Zn), aluminum (Al), indium (In), and tin (Sn). In one example, a zinc oxide (ZnO) is used to form at least a portion of the front contact layer. In one embodiment, the front end processing module is an ATON™ PVD 5.7 tool available from Applied Materials in Santa Clara, Calif. in which one or more processing steps are performed to deposit the front contact formation steps. In another embodiment, one or more CVD steps are used to form the front contact region on a surface of the substrate 302.

Next, the device substrate 303 is transported via the automation device 281 to a scribe module 208, such as the scribe module 500, in which a front contact isolation step 108 is performed on the device substrate 303 to electrically isolate different regions of the device substrate 303 surface from each other. In one embodiment, the device substrate 303 is received onto the substrate handling system 510 of the scribe module 208 with the front contact layer 310 facing upwardly, opposite the laser devices 520. In one embodiment, the substrate grippers 514 grasp opposite edges of the device substrate 303. Next, a series of encoder marks 710 are scribed in the front contact layer 310 in one or more edge regions 720 of the device substrate 303. In one embodiment, one or more encoder lines 730 and/or 731 are also scribed in the one or more edge regions 720 of the device substrate 303 substantially perpendicular to the encoder marks 710. In one embodiment, the laser device 520 is a 1064 nm wavelength pulsed laser.

Next a series of lines of trenches P1 are scribed into the front contact layer 310 of the device substrate 303 by the laser devices 520 substantially perpendicular to the encoder marks 710 as the device substrate 303 is translated through the scribe module 208. As the trenches P1 are being scribed by the laser devices 520, the vision system 840 is monitoring the encoder marks 710 and, optionally, the encoder lines 730/731. In one embodiment, as the device substrate 303 is advanced, the illumination source 842 emits light toward the encoder marks 710 and the encoder lines 730/731 (if present) while the inspection device 844 captures images of the reflected light and communicates those images in real time to the system controller 290. In response to the received images, the system controller 290 may control the positioning and frequency of pulses delivered by each laser device 520 in the scribing process to achieve good cell-to-cell and cell-to-edge isolation while minimizing the scribe area.

Next, the device substrate 303 is transported to a processing module 212 in which step 112, which comprises one or more photoabsorber deposition steps, is performed on the device substrate 303. In step 112, the one or more photoabsorber deposition steps may include one or more preparation, etching, and/or material deposition steps that are used to form the various regions of the solar cell device. Step 112 generally comprises a series of sub-processing steps that are used to form the PV layer 320 of the solar module 300. In one embodiment, the PV layer 320 comprises one or more p-i-n junctions including amorphous silicon and/or microcrystalline silicon materials. In general, the one or more processing steps are performed in one or more cluster tools (e.g., cluster tools 212A-212D) found in the processing module 212 to form one or more layers in the solar cell device formed on the device substrate 303.

Next, the device substrate 303 is transported to a scribe module 216, such as the scribe module 500, in which an interconnect formation step 116 is performed on the device substrate 303 to isolate various regions of the device substrate 303 surface from each other. In one embodiment, the device substrate 303 is received onto the substrate handling system 510 of the scribe module 216 with the PV layer 320 facing upwardly, opposite the laser devices 520. In one embodiment, the substrate grippers 514 grasp opposite edges of the device substrate 303. Next, a series of lines of trenches P2 are scribed into the PV layer 320 of the device substrate 303 by the laser devices 520 substantially perpendicular to the encoder marks 710 as the device substrate 303 is translated through the scribe module 216. In one embodiment, the laser scribe process performed during step 116 uses a 532 nm wavelength pulsed laser to pattern the material disposed on the device substrate 303 to isolate the individual cells that make up the solar module 300. As the trenches P2 are being scribed by the laser devices 520, the vision system 840 is monitoring the encoder marks 710 and, optionally, the encoder lines 730 and/or 731. In one embodiment, as the device substrate 303 is advanced, the illumination source 842 emits light toward the encoder marks 710 and the encoder lines 730/731 (if present) while the inspection device 844 captures images of the reflected light and communicates those images in real time to the system controller 290. In response to the received images, the system controller 290 may control the positioning and frequency of pulses delivered by each laser device 520 during the scribing process to achieve accurate and consistent positioning of the trenches P2. In one embodiment, the illumination source 842 may emit specific controlled wavelengths of light in order to create greater contrast between marks, gaps, or holes in the front contact layer 310 and the PV layer 320.

Next, the device substrate 303 is transported to the processing module 218 in which a back contact formation step 118 is performed on the device substrate 303. In step 118, one or more substrate back contact formation steps are performed, which may include one or more preparation, etching, and/or material deposition steps that are used to form the back contact regions of the solar cell device. In one embodiment, step 118 generally comprises one or more PVD steps that are used to form the back contact layer 350 on the surface of the device substrate 303. In one embodiment, the one or more PVD steps are used to form a back contact region that contains a metal layer selected from a group consisting of zinc (Zn), tin (Sn), aluminum (Al), copper (Cu), silver (Ag), nickel (Ni), and vanadium (V). In one example, a zinc oxide (ZnO) or nickel vanadium alloy (NiV) is used to form at least a portion of the back contact layer 350. In one embodiment, the one or more processing steps are performed using an ATON™ PVD 5.7 tool available from Applied Materials in Santa Clara, Calif. In another embodiment, one or more CVD steps are used to form the back contact layer 350 on the surface of the device substrate 303.

Next, the device substrate 303 is transported to a scribe module 220, such as the scribe module 500, in which a back contact isolation step 120 is performed on the device substrate 303 to isolate regions of the plurality of solar cells 312 contained on the device substrate 303 surface from each other. In one embodiment, the device substrate 303 is received onto the substrate handling system 510 of the scribe module 220 with the back contact layer 350 facing upwardly, opposite the laser devices 520. In one embodiment, the substrate grippers 514 grasp opposite edges of the device substrate 303. Next, a series of lines of trenches P3 are scribed into the back contact layer 350 of the device substrate 303 substantially perpendicular to the encoder marks 710 by the laser devices 520 as the device substrate 303 is translated through the scribe module 220. In one embodiment, the laser scribe process performed during step 120 uses a 532 nm wavelength pulsed laser to pattern the material disposed on the device substrate 303 to isolate the individual cells 312 that make up the solar module 300. As the trenches P3 are being scribed by the laser devices 520, the vision system 840 is monitoring the encoder marks 710 and, optionally, the encoder lines 730 and/or 731. In one embodiment, as the device substrate 303 is advanced, the illumination source 842 emits light toward the encoder marks 710 and the encoder lines 730/731 (if present) while the inspection device 844 captures images of the reflected light and communicates those images in real time to the system controller 290. In response to the received images, the system controller 290 may control the positioning and pulsing of each laser device 520 to achieve accurate and consistent positioning of the trenches P3.

Referring back to FIGS. 1 and 2, the device substrate 303 is next transported to the seamer/edge deletion module 226 in which a substrate surface and edge preparation step 126 is used to prepare various surfaces of the device substrate 303 to prevent yield issues later on in the process. In one embodiment of step 126, the device substrate 303 is inserted into seamer/edge deletion module 226 to prepare the edges of the device substrate 303 to shape and prepare the edges of the device substrate 303. Damage to the device substrate 303 edge can affect the device yield and the cost to produce a usable solar cell device. In another embodiment, the seamer/edge deletion module 226 is used to remove deposited material from the edge of the device substrate 303 (e.g., 10-12 mm) to provide a region that can be used to form a reliable seal between the device substrate 303 and the backside glass (i.e., steps 134-136 discussed below). Material removal from the edge of the device substrate 303 may also be useful to prevent electrical shorts in the final formed solar cell. In addition, the edge region 720 of the device substrate 303, in which the encoder marks 710 and, optionally, the encoder lines 730/731 are contained, may be removed during the edge preparation step 126. Thus, the encoder marks 710 and encoder lines 730/731 may be completely removed from the device substrate 303 prior to completing the fabrication of the solar module 300.

In one embodiment, a diamond impregnated belt is used to grind the deposited material from the edge regions of the device substrate 303. In another embodiment, a grinding wheel is used to grind the deposited material from the edge regions of the device substrate 303. In another embodiment, dual grinding wheels are used to remove the deposited material from the edge of the device substrate 303. In yet another embodiment, grit blasting or laser ablation techniques are used to remove the deposited material from the edge of the device substrate 303. In one aspect, the seamer/edge deletion module 226 is used to round or bevel the edges of the device substrate 303 by use of shaped grinding wheels, angled and aligned belt sanders, and/or abrasive wheels.

Next the device substrate 303 is transported to the pre-screen module 227 in which optional pre-screen steps 127 are performed on the device substrate 303 to assure that the devices formed on the substrate surface meet a desired quality standard. In step 127, a light emitting source and probing device are used to measure the output of the formed solar cell device by use of one or more substrate contacting probes. If the module 227 detects a defect in the formed device it can take corrective actions or the solar cell can be scrapped.

Next the substrate 303 is transported to a bonding wire attach module 231 in which step 131, or a bonding wire attach step, is performed on the substrate 303. Step 131 is used to attach the various wires/leads required to connect the various external electrical components to the formed solar cell device. Typically, the bonding wire attach module 231 is an automated wire bonding tool that is advantageously used to reliably and quickly form the numerous interconnects that are often required to form the large solar cells formed in the production line 200. In one embodiment, the bonding wire attach module 231 is used to form the side-buss 314 (FIG. 3) and cross-buss 316 on the formed back contact layer 350 (step 118). In this configuration the side-buss 314 may be a conductive material that can be affixed, bonded, and/or fused to the back contact layer 350 found in the back contact region to form a good electrical contact. In one embodiment, the side-buss 314 and cross-buss 316 each comprise a metal strip, such as copper tape, a nickel coated silver ribbon, a silver coated nickel ribbon, a tin coated copper ribbon, a nickel coated copper ribbon, or other conductive material that can carry the current delivered by the solar cell and be reliably bonded to the metal layer in the back contact region. In one embodiment, the metal strip is between about 2 mm and about 10 mm wide and between about 1 mm and about 3 mm thick. The cross-buss 316, which is electrically connected to the side-buss 314 at the junctions, can be electrically isolated from the back contact layer(s) of the solar cell by use of an insulating material, such as an insulating tape. The ends of each of the cross-busses 316 generally have one or more leads that are used to connect the side-buss 314 and the cross-buss 316 to the electrical connections found in a junction box 308, which is used to connect the formed solar cell to the other external electrical components.

In the next step, step 132, a bonding material and “back glass” substrate are prepared for delivery into the solar cell formation process (i.e., process sequence 100). The preparation process is generally performed in the glass lay-up module 232, which generally comprises a material preparation module 232A, a glass loading module 232B, a glass cleaning module 232C, and a glass inspection module 232D. The back glass substrate is bonded onto the device substrate 303 formed in steps 102-131 above by use of a laminating process (step 134 discussed below). In general, step 132 requires the preparation of a polymeric material that is to be placed between the back glass substrate and the deposited layers on the device substrate 303 to form a hermetic seal to prevent the environment from attacking the solar cell during its life. Referring to FIG. 2, step 132 generally comprises a series of sub-steps in which a bonding material is prepared in the material preparation module 232A, the bonding material is then placed over the device substrate 303, and the back glass substrate is loaded into the loading module 232B. The back glass substrate is washed by the cleaning module 232C. The back glass substrate is then inspected by the inspection module 232D, and the back glass substrate is placed over the bonding material and the device substrate 303.

In the next sub-step of step 132, the back glass substrate is transported to the cleaning module 232C in which a substrate cleaning step, is performed on the substrate to remove any contaminants found on the surface of the substrate. Common contaminants may include materials deposited on the substrate during the substrate forming process (e.g., glass manufacturing process) and/or during shipping of the substrates. Typically, the cleaning module 232C uses wet chemical scrubbing and rinsing steps to remove any undesirable contaminants as discussed above.

The prepared back glass substrate is then positioned over the bonding material and partially device substrate 303 by use of an automated robotic device.

Next the device substrate 303, the back glass substrate, and the bonding material are transported to the bonding module 234 in which step 134, or lamination steps are performed to bond the backside glass substrate to the device substrate formed in steps 102-132 discussed above. In step 134, a bonding material, such as Polyvinyl Butyral (PVB) or Ethylene Vinyl Acetate (EVA), is sandwiched between the backside glass substrate and the device substrate 303. Heat and pressure are applied to the structure to form a bonded and sealed device using various heating elements and other devices found in the bonding module 234. The device substrate 303, the back glass substrate and bonding material thus form a composite solar cell structure 304 that at least partially encapsulates the active regions of the solar cell device. In one embodiment, at least one hole formed in the back glass substrate remains at least partially uncovered by the bonding material to allow portions of the cross-buss 316 or the side buss 314 to remain exposed so that electrical connections can be made to these regions of the solar cell structure 304 in future steps (i.e., step 138).

Next the composite solar cell structure 304 is transported to the autoclave module 236 in which step 136, or autoclave steps are performed on the composite solar cell structure 304 to remove trapped gasses in the bonded structure and assure that a good bond is formed during step 136. In step 136, a bonded solar cell structure 304 is inserted in the processing region of the autoclave module where heat and high pressure gases are delivered to reduce the amount of trapped gas and improve the properties of the bond between the device substrate 303, back glass substrate, and bonding material. The processes performed in the autoclave are also useful to assure that the stress in the glass and bonding layer (e.g., PVB layer) are more controlled to prevent future failures of the hermetic seal or failure of the glass due to the stress induced during the bonding/lamination process. In one embodiment, it may be desirable to heat the device substrate 303, back glass substrate, and bonding material to a temperature that causes stress relaxation in one or more of the components in the formed solar cell structure 304.

Next the solar cell structure 304 is transported to the junction box attachment module 238 in which junction box attachment steps 138 are performed on the formed solar cell structure 304. The junction box attachment module 238, used during step 138, is used to install a junction box 308 (FIG. 3) on a partially formed solar module. The installed junction box 308 acts as an interface between the external electrical components that will connect to the formed solar module, such as other solar modules or a power grid, and the internal electrical connections points, such as the leads, formed during step 131. In one embodiment, the junction box 308 contains one or more connection points so that the formed solar module can be easily and systematically connected to other external devices to deliver the generated electrical power.

Next, the solar cell structure 304 is transported to the device testing module 240 in which device screening and analysis steps 140 are performed on the solar cell structure 304 to assure that the devices formed on the solar cell structure 304 surface meet desired quality standards. In one embodiment, the device testing module 240 is a solar simulator module that is used to qualify and test the output of the one or more formed solar cells. In step 140, a light emitting source and probing device are used to measure the output of the formed solar cell device by use of one or more automated components that are adapted to make electrical contact with terminals in the junction box 308. If the module detects a defect in the formed device it can take corrective actions or the solar cell can be scrapped.

Next the solar cell structure 304 is transported to the support structure module 241 in which support structure mounting steps 141 are performed on the solar cell structure 304 to provide a complete solar cell device that has one or more mounting elements attached to the solar cell structure 304 formed using steps 102-140 to a complete solar cell device that can easily be mounted and rapidly installed at a customer's site.

Next the solar cell structure 304 is transported to the unload module 242 in which step 142, or device unload steps are performed on the substrate to remove the formed solar cells from the solar module production line 200.

While the foregoing is directed to embodiments of the present invention, other and further embodiments of the invention may be devised without departing from the basic scope thereof, and the scope thereof is determined by the claims that follow.

1. An apparatus for scribing lines in one or more layers disposed on a first surface of a solar cell device substrate, comprising:
a substrate handling device configured to support and move the device substrate, wherein the substrate handling device supports the device substrate in a position with the first surface facing upwardly;
a laser device positioned below a second surface of the device substrate that is opposite the first surface and configured to remove a portion of at least one of the one or more layers from the device substrate;
a vision system positioned below the second surface of the device substrate and configured to monitor one or more edge regions of the device substrate while the portion of at least one of the one or more layers is removed from the device substrate; and
a system controller in communication with the substrate handling device, the laser device, and the vision system, wherein the system controller is configured to control removal of the portion of at least one of the one or more layers from the device substrate based on information received from the vision system regarding the one or more monitored edge regions.

2. The apparatus of claim 1, wherein the vision system comprises an illumination source positioned to illuminate the one or more edge regions and an imaging device configured to capture images of the one or more illuminated edge regions.

3. The apparatus of claim 2, wherein the illumination source is positioned to emit light at a first angle with respect to the second surface of the device substrate, and wherein the imaging device is positioned at a second angle with respect to the second surface of the device substrate.

4. The apparatus of claim 3, wherein the first and second angles are complementary.

5. The apparatus of claim 2, wherein the one or more edge regions have a plurality of encoder marks scribed into at least one of the one or more layers.

6. The apparatus of claim 5, wherein the substrate handling device is configured to move the device substrate in a lateral direction with respect to the laser device and the vision system, and wherein the plurality of encoder marks are positioned substantially perpendicular to the lateral direction.

7. The apparatus of claim 5, wherein the laser device and the vision system are configured to move in a lateral direction with respect to the device substrate positioned on the substrate handling device, and wherein the plurality of encoder marks are positioned substantially perpendicular to the lateral direction.

8. A method for scribing lines in one or more layers of a solar cell device substrate, comprising:
causing relative motion between the device substrate and a laser device in a first direction;
illuminating an edge region of the device substrate having a plurality of encoder marks scribed therein during the relative motion;
capturing images of the plurality of encoder marks within the edge region during the illuminating the edge region; and
adjusting a frequency or position of a plurality of pulses delivered by the laser device to the device substrate based on the captured images of the plurality of encoder marks within the edge region of the device substrate.

9. The method of claim 8, wherein the plurality of encoder marks are positioned substantially perpendicular to the first direction.

10. The method of claim 9, wherein the edge region further comprises one or more encoder lines positioned substantially perpendicular to the plurality of encoder marks.

11. The method of claim 9, wherein the illuminating the edge region comprises emitting light toward the edge region of the device substrate at a first angle with respect to a surface of the device substrate.

12. The method of claim 11, wherein the emitting light is at a wavelength between about 400 nm and about 900 nm.

13. The method of claim 11, wherein the capturing images comprises positioning an imaging device at a second angle with respect to the surface of the device substrate, wherein the first and second angles are substantially complementary.

14. The method of claim 9, wherein the causing relative motion comprises moving the device substrate with respect to the laser device.

15. The method of claim 9, wherein causing relative motion comprises moving the laser device with respect to the device substrate.

16. A system for fabricating solar cell modules, comprising:
a first scribing module having a first laser device and a first vision system, wherein the first laser device is configured to scribe a plurality of encoder marks on a substrate, wherein the first laser device is further configured to scribe one or more first trenches in a front contact layer disposed on the substrate, and wherein the first vision system is configured to monitor the plurality of encoder marks while the first laser device scribes the one or more first trenches;
one or more cluster tools having at least one chamber configured to deposit at least one photovoltaic layer over the front contact layer;
a second scribing module having a second laser device and a second vision system, wherein the second laser device is configured to scribe one or more second trenches in the at least one photovoltaic layer of the substrate, and wherein the second vision system is configured to monitor the plurality of encoder marks while the second laser device scribes the one or more second trenches; and
a system controller configured to control the first laser device based on information received from the first vision system and configured to control the second laser device based on information received from the second vision system.

17. The system of claim 16, wherein the first laser device is configured to scribe the one or more first trenches substantially perpendicular to the plurality of encoder marks, and wherein the second laser device is configured to scribe the one or more second trenches substantially perpendicular to the plurality of encoder marks.

18. The system of claim 17, further comprising:
a deposition module configured to deposit a back contact layer over the at least one photovoltaic layer;
a third scribing module having a third laser device and a third vision system, wherein the third laser device is configured to scribe one or more third trenches in the back contact layer of the substrate, and wherein the third vision system is configured to monitor the plurality of encoder marks while the third laser device scribes the one or more third trenches, and wherein the system controller is further configured to control the third laser device based on information received from the third vision system.

19. The system of claim 18, wherein the third laser device is configured to scribe the one or more third trenches substantially perpendicular to the plurality of encoder marks.

20. The system of claim 18, further comprising an edge delete module configured to remove the back contact layer, the at least one photovoltaic layer, and the front contact layer from the edge region of the substrate.
